(19) United States
(12) Patent Application Publication
(10) Pub. No.: US 2006/0252248 A1
(43) Pub. Date: Nov. 9, 2006

(54) Method for fabricating electrically connecting structure of circuit board

(76) Inventor: Wen-Hung Hu, Hsin-chu (TW)

Correspondence Address: SAWYER LAW GROUP LLP, P O BOX 51418, PALO ALTO, CA, 94303, US

(21) Appl. No.: 11/429,882

(22) Filed: May 8, 2006

(30) Foreign Application Priority Data
May 9, 2005 (TW) 094114845

(51) Int. Cl. H01L 21/44

(52) U.S. Cl. 438/613

(57) ABSTRACT

A method for fabricating an electrically connecting structure of a circuit board is proposed. An insulating protecting layer is formed on a circuit board having electrically connecting pads and has openings to expose the electrically connecting pads. A resist layer with openings corresponding to the electrically connecting pads is formed on a conductive layer formed on the insulating protecting layer. A metal layer is formed in the openings of the resist layer and fills the openings. The resist layer is removed. The metal layer and the conductive layer on the surface of the insulating protecting layer are removed by thinning processing, so as to form a metal bump. An adhesive layer is formed on an exposed surface of the metal bump, so as to form the electrically connecting structure for electrically connecting the circuit board to an external electronic device.

### CROSS-REFERENCE TO RELATED APPLICATION

This application claims benefit under 35 USC 119 of Taiwan Application No. 094114845, filed May 9, 2005.

### FIELD OF THE INVENTION

This invention relates to a method for fabricating an electrically connecting structure of a circuit board, and more particularly, to a method for fabricating an electrically connecting structure formed on electrically connecting pads of the circuit board for electrically connecting the circuit board to an external electronic device.

### BACKGROUND OF THE INVENTION

A flip chip package technique was introduced to the market by International Business Machine (IBM) Co. in early 1960's. Compared with a wire bond technique, the flip chip package technique has a characteristic that a semiconductor chip is electrically connected to a substrate by solder bumps, rather than by gold wires. A semiconductor component made by the flip chip package technique has a smaller size and a larger density. Moreover, because the flip chip package technique does not install any gold wire on the semiconductor component, the semiconductor component has better electric characteristics. Accordingly, a control-collapse chip connection (C4) technique, which installs high temperature solders on a ceramic substrate, is introduced to the market. In recent years, a semiconductor component is required to have a high density but a low cost, and be capable of operating at a high frequency. In order to follow a trend of an electronic device towards compact size, the semiconductor component (i.e. a silicon chip) made by the flip chip package technique is generally installed on a low cost organic circuit board (for example, a printed circuit board or a substrate), and an underfill resin is filled under the silicon chip for reducing a heat stress due to a thermal expansion difference between the silicon chip and the organic circuit board.

According to a modem flip chip package technique, a plurality of electrode pads and contact pads are installed on a semiconductor integrated circuit (IC) chip and an organic circuit board respectively. Therefore, a plurality of solder bumps and other conductive solder materials can be installed in a region between the semiconductor IC chip and the organic circuit board, and the semiconductor IC chip is installed on and electrically connected to the organic circuit board. The solder bumps and conductive solder materials not only provide mechanical connection for the semiconductor IC chip and the organic circuit board, but also serve as electrically connecting inputs/outputs between the semiconductor IC chip and the organic circuit board.

As shown in FIG. 1, the flip chip package technique forms a plurality of metal bumps 11 on a plurality of electrode pads 12 of a chip 13, forms a plurality of pre-solder bumps 14 made of solder on a plurality of electrically connecting pads 15 of a circuit board 16, and reflows the pre-solder bumps 14 onto the metal bumps 11 correspondingly in a reflow oven at a temperature high enough to melt the pre-solder bump 14 to form a plurality of solder bonds 17. The flip chip package technique then couples the chip 13 with the circuit board 16 with an underfill material 18, to ensure the integrity and reliability of electric connection between the chip 13 and the circuit board 16.

In order that the circuit board 16 can be electrically connected to an external electronic device, the flip chip package technique further forms solder materials on the electrically connecting pads 15 of the circuit board 16 for a plurality of solder balls to be planted on, and plants the solder balls on the solder materials so that the solder balls can be installed on the circuit board 16 steadily.

A stencil printing technique is one of the most popular methods for forming the solder materials on the electrically connecting pads 15 of the circuit board 16 in the art. As shown in FIG. 2, the stencil printing technique forms a plurality of electrically connecting pads 22 on a circuit board 20 having a layout already, forms a solder mask 21 on the circuit board 20 except the electrically connecting pads 22, installs a stencil 23 having a plurality of openings 23a on the solder mask 21, sprays and levels solder materials in the openings 23 with a wheel 24, and removes the stencil 23, so as to form on each of the electrically connecting pads 22 a solder pile (not shown), which will become a pre-solder structure after the circuit board 20 is placed in a reflow oven.

As a semiconductor chip is required to have a smaller size but more input/output pins, electrically connecting pads of the semiconductor chip have to have smaller sizes and be installed more densely on a chip carrier (i.e. the circuit board 20) of the semiconductor chip. Accordingly, the stencil printing technique has to make a stencil having small enough openings. However, too small the openings not only increase the cost of the stencil, but also restrict the passing of solder, material, forming a manufacturing bottleneck. Moreover, that the solder materials are required to be formed in the openings so accurately not only ensures the correctness of size of the stencil, but also closely relates to a cleaning problem of the stencil printing technique. Because the solder materials have viscosities, the larger a number of a printing process applied by the stencil printing technique on the stencil, the more the solder materials are piled on the openings of the stencil. In result, the number of the solder materials are changed and the solder materials are deformed. Therefore, the stencil has to be cleaned completely every time the printing process is applied by the stencil printing technique on the stencil, this complicating a manufacturing process and reducing the reliability of the stencil.

Moreover, in order to ensure that the electrically connecting pads of the circuit board are electrically connected to the pre-solder structure and prevent the electrically connecting pads from oxidation, a nickel/gold bi-metal layer and an organic solderability preservative (OSP) layer are further formed on the electrically connecting pads by a chemical deposition method and an OSP process respectively. However, if gaps between the electrically connecting pads keep narrowing, an insulating protecting layer covered on the circuit board and disposed around the electrically connecting pads will cover part of the electrically connecting pads eventually. In result, the electrically connecting pads have smaller size equivalently, and both the nickel/gold bi-metal layer and the OSP layer are difficult to be formed on such the small electrically connecting pads because the insulating protecting layer have too small openings, resulting in a skip plating phenomenon and complicating succeeding manufacture processes.

### SUMMARY OF THE INVENTION

In views of the above-mentioned problems of the prior art, it is a primary objective of the present invention to provide a method for fabricating an electrically connecting structure of a circuit board, for preventing from a restriction of the size of solder bumps formed by a stencil printing technique of the prior art, cost increasing and a bottleneck of a manufacturing technique.

It is another objective of the present invention to provide a method for fabricating an electrically connecting structure of a circuit board, for preventing from a skip plating phenomenon of the prior art resulting from the formation of the nickel/gold bi-metal layer or the OSP layer in too small the openings of the insulating protecting layer by the chemical deposition process, and to complicating succeeding manufacture processes.

It is a further objective of the present invention to provide a method for fabricating an electrically connecting structure of a circuit board, for forming an electrically connecting structure formed on electrically connecting pads having narrow gaps of a circuit board for electrically connecting the circuit board to an external electronic device.

To achieve the above-mentioned and other objectives, a method for fabricating an electrically connecting structure of a circuit board is provided according to the present invention. The method includes providing a circuit board comprising a plurality of electrically connecting pads on at least one surface of the circuit board, and forming on the surface of the circuit board an insulating protecting layer comprising a plurality of openings for exposure of the electrically connecting pads; forming a conductive layer on the insulating protecting layer and the openings of the insulating protecting layer; forming on the conductive layer a resist layer comprising a plurality of openings corresponding to the electrically connecting pads; forming a metal layer on the conductive layer exposed by the openings of the resist layer with an electroplating process, and filling the metal layer in the openings of the insulating protecting layer; removing the resist layer, and removing part of the metal layer and the conductive layer above the insulating protecting layer with a thinning process, so as to form on each of the electrically connecting pads a metal bump; and forming an adhesive layer on a surface of the metal bump exposed by each of the openings of the insulating protecting layer, so as to form the electrically connecting structure for electrically connecting the circuit board to an external electronic device.

Another preferred embodiment of a method for fabricating an electrically connecting structure of a circuit board includes the following steps: providing a circuit board comprising a plurality of electrically connecting pads on at least one surface of the circuit board, and forming on the surface of the circuit board an insulating protecting layer comprising a plurality of openings for exposure of the electrically connecting pads; forming a conductive layer on the insulating protecting layer and the openings of the insulating protecting layer; forming a metal layer on the conductive layer with an electroplating process, and filling the metal layer in the openings of the insulating protecting layer; removing part of the metal layer and the conductive layer above the insulating protecting layer with a thinning process, and keeping a remaining part of the metal layer and the conductive layer filled in the openings of the insulating protecting layer opening, so as to form on each of the electrically connecting pads a metal bump; and forming an adhesive layer on a surface of the metal bump exposed by each of the openings of the insulating protecting layer, so as to form the electrically connecting structure for the electrically connecting the circuit board to an external electronic device.

Another preferred embodiment of a method for fabricating an electrically connecting structure of a circuit board includes the following steps: providing a circuit board comprising a plurality of electrically connecting pads on at least one surface of the circuit board, and forming on the surface of the circuit board an insulating protecting layer having a plurality of openings for exposure of the electrically connecting pads; forming a conductive layer on the insulating protecting layer and the openings of the insulating protecting layer; forming on the conductive layer a resist layer having a plurality of openings corresponding to the electrically connecting pads; forming a metal layer on the conductive layer exposed by the openings of the resist layer with an electroplating process, and filling the metal layer in the openings of the insulating protecting layer; removing the metal layer and the conductive layer above the insulating protecting layer with a thinning process, and keeping the metal layer and the conductive layer filled in the openings of the insulating protecting layer, so as to form a metal bump on each of the electrically connecting pads; and removing the resist layer and the conductive layer covered by the resist layer, and forming an adhesive layer on a surface of the metal bump exposed by each of the openings of the insulating protecting layer, so as to form the electrically connecting structure for electrically connecting the circuit board to an external electronic device. The adhesive layer is one selected from a group consisting of a solder material, a nickel/gold bi-metal layer, gold, electroless plating tin, electroless plating silver and an OSP layer.

Compared with the prior art, the present invention makes the use of an electroplating technique on an electroplating copper material, which is cheap and easy to be electroplated, to form a metal layer of copper first, so as to reduce manufacturing time. The present invention then forms a solder material, a metal layer or an adhesive layer of an OSP layer, which are all expensive, so as to reduce the manufacture time and the consumption of the solder material. Moreover, the present invention solves solder bridge and short circuited problems resulting from too many the melted solder materials in a reflow process, and can provide a plurality of electrically connecting pads with small pin intervals. The present invention further releases the restriction on the size of solder bump and the pin intervals of neighboring electrically connecting pads formed by the stencil printing technique, reduces the manufacturing cost, and eliminates the bottleneck in a manufacturing process.

Moreover, the present invention further makes the use of the electroplating process to form a metal bump on the electrically connecting pads of the circuit board and corresponding to the openings of the insulating protecting layer, and forms an adhesive layer, such as a solder material, a metal layer or an OSP layer, on an exposing surface of the metal bump outside the insulating protecting layer. Therefore, the skip plating phenomenon of the prior art resulting from the formation of the solder material, the metal layer or the OSP layer in too small the openings of the insulating protecting layer and the complication of the succeeding manufacture processes are solved.

### BRIEF DESCRIPTION OF DRAWINGS

The invention can be more fully understood by reading the following detailed description of the preferred embodiments, with reference made to the accompanying drawings, wherein:

FIG. 1 is a cross sectional schematic diagram of a flip chip component according to the prior art;

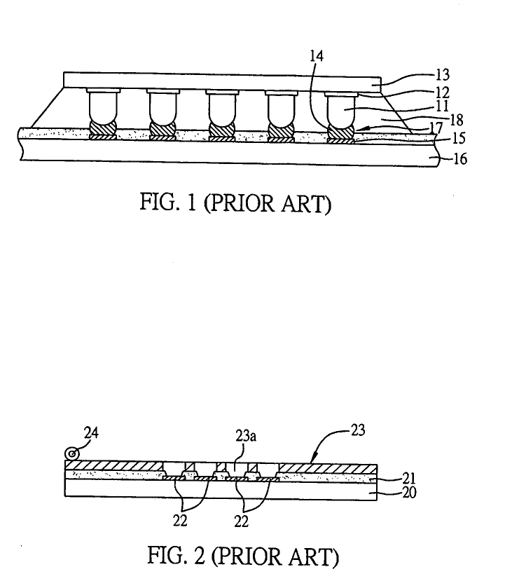

FIG. 2 is a cross sectional schematic diagram illustrating depositing solder materials on electrically connecting pads of a circuit board by a stencil printing technique according to the prior art;

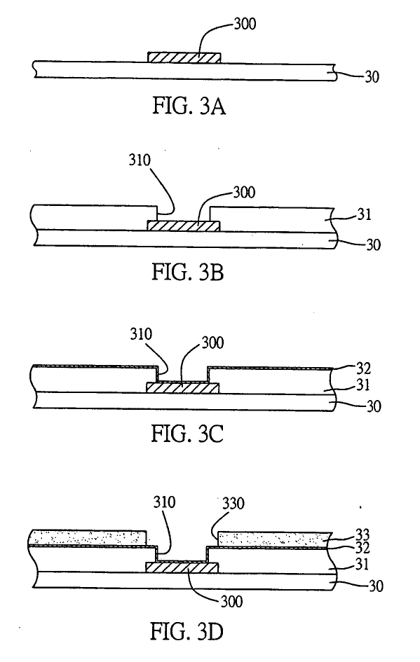

FIGS. 3A to 3G are cross sectional schematic diagrams of a first embodiment of a method for fabricating an electrically connecting structure of a circuit board according to the present invention;

FIG. 4A illustrates forming solder materials on metal bumps exposed to a region outside of openings of the insulating protecting layer of a method for fabricating an electrically connecting structure according to the present invention;

FIG. 4B is a cross sectional schematic diagram illustrating performing a reflow process on metal bumps to form solder bumps in a method for fabricating an electrically connecting structure according to the present invention;

FIGS. 5 and 6 are cross sectional schematic diagrams illustrating forming a metal layer and an OSP layer on exposed surfaces of metal bumps in a method for fabricating an electrically connecting structure according to the present invention;

FIGS. 7A to 7D are cross sectional schematic diagrams of a second embodiment of an electrically connecting structure of a circuit board according to the present invention; and

FIGS. 8A to 8F are cross sectional schematic diagrams of a third embodiment of an electrically connecting structure of a circuit board according to the present invention

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

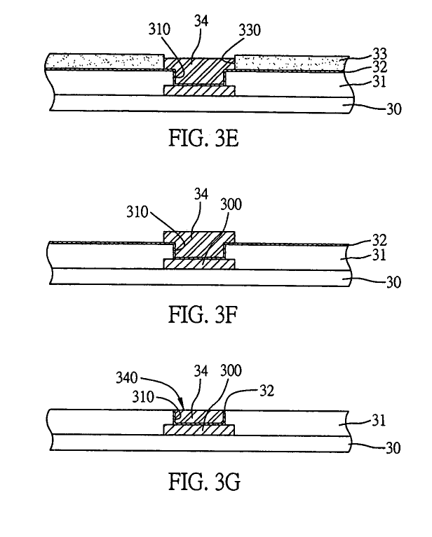

FIGS. 3A to 3G, 4A to 4B, 5 and 6 illustrate a method for fabricating an electrically connecting structure of a circuit board of a first embodiment according to the present invention.

Please refer to FIG. 3A. A plurality of electrically connecting pads 300 and a conductive line (not shown) are formed on a circuit board 30, which has a layout already. Manufacturing techniques for forming the conductive line and the electrically connecting pads 300 on the circuit board 30 are prior arts, further description hereby omitted.

Please refer to FIG. 3B. An insulating protecting layer 31 having a plurality of openings 310 for exposure of the electrically connecting pads 300 is further formed on the circuit board 30. According to the embodiment, the insulating protecting layer 31 is formed on the circuit board 30 by a printing, a spin coating or an adhering technique first, and then a patterning technique. The insulating protecting layer 31 is made of green paint, which has epoxy resin as a substrate and is one kind of solder mask materials having a dewetting characteristic, or made of an organic or an inorganic anti-oxidant membrane, both of which also have the dewetting characteristic.

Please refer to FIG. 3C. A conductive layer 32 is further formed on the insulating protecting layer 31 and the openings 310. The conductive layer 32 acts as a current transmission route needed by succeeding electroplating metal materials and is in a form of an alloy or multiple metal layers comprising at least one selected from a group consisting of copper, tin, nickel, chromium, titanium and an alloy of tin and lead, or can be made of a conductive macromolecule material, such as polyacetylene, polyaniline and organic sulfur polymer.

Please refer to FIG. 3D. A resist layer 33 is further formed on the circuit board 30. The resist layer 33 is a photoresist layer, such as a dry film photoresist and a liquid photoresist, and is formed on the conductive layer 32 and having a plurality of openings 330 corresponding to the electrically connecting pads 300 also by the printing, the spin coating or the adhering technique first, and then by the patterning technique, such as an exposing and a developing technique.

Please refer to FIG. 3E. A metal layer 34 is further filled in the openings 310 of the insulating protecting layer 31 by performing on the circuit board 30 an electroplating process, which takes the conductive layer 32, which has a conductive characteristic, as the current transmission route. According to the embodiment, the metal layer 34 is made of at least one selected from a group consisting of lead, tin, silver and copper. In general, because copper is a mature electroplating material and is cheap, the metal layer 34 is preferably made of, but is not limited to, the electroplated copper.

Please refer to FIG. 3F. The resist layer 33 has been stripped from the conductive layer 32 by a chemical stripping technique.

Please refer to FIG. 3G One part of the metal layer 34 and conductive layer 32 above the protecting layer 31 are removed by a thinning process, and the other part of the metal layer 34 and conductive layer 32, which correspond to the electrically connecting pads 300 and is filled in the openings 310 of the insulating protecting layer 31, are still remained, so as to form on each of the electrically connecting pads 300 a metal bump 340, which comprises the stripped metal layer 34 and conductive layer 32. According to the embodiment, the thinning process is, but is not limited to, an etching, a buff and an abrasive technique.

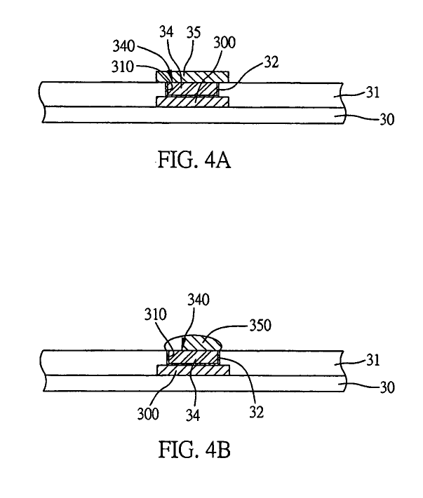

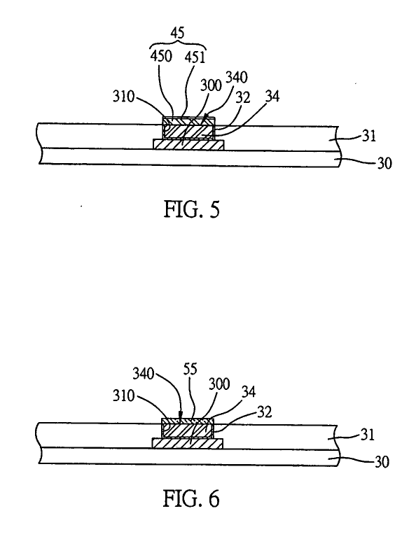

Please refer to FIG. 4A. A solder material 35 having a certain thickness in formed on the metal bump 340, which is exposed to a region outside of the opening 310 of the insulating protecting layer 31, by the stencil printing technique or a physical or chemical deposition technique.

Please refer to FIG. 4B. A solder bump 350 is formed on the metal bump 340 by performing on the solder material 35 a reflow process at a temperature higher enough to melt the solder material 35. As shown in FIG. 4B, an exposing surface of the metal bump 340 is covered by the solder bump 350 completely.

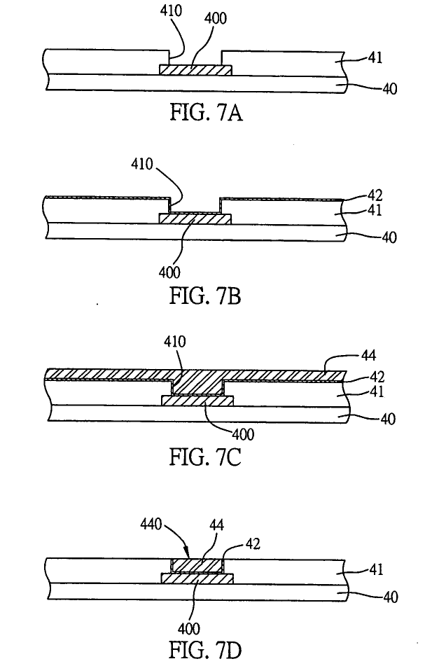

Please refer to FIG. 5 and FIG. 6. An adhesive layer 45 comprising a nickel layer 450 and a gold layer 451 is further formed and covered on the exposing surface of the metal bump 340 by the physical or chemical deposition process or an electroless plating process. The nickel layer 450 is formed on the exposing surface of the metal bump 340, and the gold layer 451 is formed on the nickel layer 450 (as shown in FIG. 5). Instead of the adhesive layer 45, a gold, an electroless plating tin or an electroless plating silver layer, or another adhesive having an OSP layer 55 (as shown in FIG. 6) can be formed on the metal bump 340, so as to solve the skip plating phenomenon of the prior art resulting from the formation of the nickel/gold bi-metal layer or the OSP layer in too small the openings of the insulating protecting layer by the chemical deposition process, and to simplify the succeeding manufacture processes.

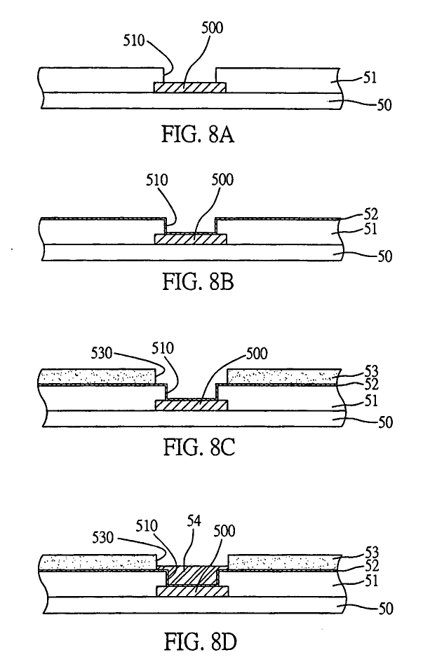

Please refer to FIGS. 7A to 7D, which illustrate another method for fabricating an electrically connecting structure of a second embodiment according to the present invention. The method is generally similar to the method described previously. In particular, in the second embodiment a conductive layer is formed on an insulating protecting layer and a plurality of openings of the insulating protecting layer, a metal layer is formed on the conductive layer by the electroplating process, the metal layer is filled in the openings of the insulating protecting layer, and the metal and conductive layer, after the thinning process, in the openings of the insulating protecting layer are remained.

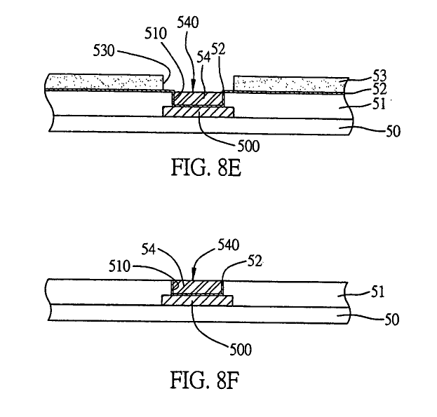

Please refer to FIG. 8. An insulating protecting layer 41 is formed on a circuit board 40 having a plurality of electrically connecting pads 400. the insulating protecting layer 41 comprises a plurality of openings 410 for exposure of the electrically connecting pads 400.

Please refer to FIG. 7B. A conductive layer 42 is formed on the insulating protecting layer 41 and the openings 410. The conductive layer 42 acts as a current transmission route needed by succeeding electroplating metal materials, and is made of metal, an alloy or multiple metal layers, or conductive polymer materials.

Please refer to FIG. 7C. A metal layer 44 is further filled in the openings 410 of the insulating protecting layer 41 by performing on the conductive layer 42 the electroplating process, which takes the conductive layer 42, which has the conductive characteristic, as the current transmission route. According to the embodiment, the metal layer 44 is made of at least one selected from a group consisting of lead, tin, silver and copper. In general, because copper is a mature electroplating material and is cheap, the metal layer 44 is preferably made of, but is not limited to, the electroplated copper.

Please refer to FIG. 7D. One part of the metal layer 44 and conductive layer 42 above the protecting layer 41 are removed by the thinning process, and the other part of the metal layer 44 and conductive layer 42, which is filled in the openings 410 of the insulating protecting layer 41, are still remained, so as to form on each of the electrically connecting pads 400 of the circuit board 40 a metal bump 440. According to the embodiment, the thinning process is, but is not limited to, an etching, a buff and an abrasive technique.

A solder material, a nickel/gold bi-metal layer (as shown in FIGS. 4A and 4B) or an adhesive layer of OSP layer (as shown in FIG. 6) is formed on the metal bump 440, which is exposed to a region outside of the openings 410 of the insulating protecting layer 41.

Please refer to FIGS. 8A to 8F, which illustrate another method for fabricating an electrically connecting structure of a third embodiment according to the present invention. In general, the method is similar to the method of the first embodiment. In particular, the method of the third embodiment first forms a conductive layer and a metal layer on an insulating protecting layer and a plurality of openings of the insulating protecting layer, thins and removes part of the conductive layer and metal layer above the insulating protecting layer, keeping the remaining part of the conductive layer and metal layer in the openings of the insulating protecting layer, and removes the resist layer and part of the conductive layer coved by the resist layer.

Please refer to FIG. 8A. An insulating layer 51 is formed on a circuit board 50 having a plurality of electrically connecting pads 500. The insulating layer 51 comprises a plurality of openings 510 for exposure of the openings 510 of the insulating protecting layer 51.

Please refer to FIG. 8B. A conductive layer 52 is formed on the insulating protecting layer 51 and the openings 510. The conductive layer 52 acts as the current transmission route needed by the succeeding electroplating metal materials, and is made of metal, an alloy or multiple metal layers or conductive polymer materials.

Please refer to FIG. 8C. A resist layer 53 having a plurality of openings 530 corresponding to the electrically connecting pads 500 is formed on the conductive layer 52.

Please refer to FIG. 8D. A metal layer 54 is filled in the openings 510 of the insulating protecting layer 51 and covered on part of the openings 530 of the resist layer 53 by an electroplating process. The metal layer 54 is made of lead, tin, silver and copper or an alloy of these metal. In general, because copper is a mature electroplating material and is cheap, the metal layer 54 is preferably made of, but is not limited to, the electroplated copper.

Please refer to FIG. 8E. Part of the metal layer 54 and the conductive layer 52 above the insulating protecting layer 51 is removed by a tinning process, and the other part of the metal layer 54 and the conductive layer 52 in the openings 510 of the insulating protecting layer 51 is remained, so as to form a metal bump 540 on the metal layer 54 and the conductive layer 52. According to the embodiment, the thinning process is an etching process.

Please refer to FIG. 8F. The resist layer 53 and the conductive layer 52, which is covered by the resist layer 53, are removed by a chemical stripping technique.

In the thinning process mentioned in FIG. 8E, the thinning process can remove the metal layer 54 and the conductive layer 52 formed on the insulating protecting layer 51 after the resist layer 53 is removed.

Therefore, the solder material (as shown in FIGS. 4A and 4B), the nickel/gold bi-metal layer (as shown in FIG. 5) and the OSP layer of the adhesive layer (as shown in FIG. 6) can be formed on the metal bump 540, which is exposed to a region outside of the openings 510 of the insulating protecting layer 51.

In summary, the method for fabricating an electrically connecting structure of a circuit board forms an insulating protecting layer on a circuit board having a plurality of electrically connecting pads, the insulating protecting layer having a plurality of openings for exposure of the electrically connecting pads. The method further forms a conductive layer on the insulating protecting layer and in the openings of the insulating protecting layer, forms a metal layer on the conductive layer by an electroplating process, removes part of the metal layer and the conductive layer above the insulating protecting layer, and keeps the other part of the metal layer and the conductive layer formed in the openings of the insulating protecting layer, so as to form a metal bump on the each of the electrically connecting pads. Therefore, an adhesive layer, such as a solder material, a nickel/gold bi-metal layer, gold, a metal layer made of electroless plating tin or electroless plating silver, or an OSP layer, can be formed on an exposing surface of the metal surface, so as to form an electrically connecting structure for electrically connecting the circuit board to an external electronic device.

Compared with the prior art, the present invention makes the use of an electroplating technique on an electroplating copper material, which is cheap and easy to be electroplated, to form a metal layer of copper first, so as to reduce manufacturing time. The present invention then forms a solder material, a metal layer or an adhesive layer of an OSP layer, which are all expensive, so as to reduce the manufacture time and the consumption of the solder material. Moreover, the present invention solves solder bridge and short circuited problems resulting from too many the melted solder materials in a reflow process, and can provide a plurality of electrically connecting pads with small pin intervals. The present invention further releases the restriction on the size of solder bump and the pin intervals of neighboring electrically connecting pads formed by the stencil printing technique, reduces the manufacturing cost, and eliminates the bottleneck in a manufacturing process.

Moreover, the present invention further makes the use of the electroplating process to form a metal bump on the electrically connecting pads of the circuit board and corresponding to the openings of the insulating protecting layer, and forms an adhesive layer, such as a solder material, a metal layer or an OSP layer, on an exposing surface of the metal bump outside the insulating protecting layer. Therefore, the skip plating phenomenon of the prior art resulting from the formation of the solder material, the metal layer or the OSP layer in too small the openings of the insulating protecting layer and the complication of the succeeding manufacture processes are solved.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method for fabricating an electrically connecting structure of a circuit board, the method comprising:
providing a circuit board comprising a plurality of electrically connecting pads on at least one surface of the circuit board, and forming on the surface of the circuit board an insulating protecting layer comprising a plurality of openings for exposure of the electrically connecting pads;
forming a conductive layer on the insulating protecting layer and the openings of the insulating protecting layer;
forming on the conductive layer a resist layer comprising a plurality of openings corresponding to the electrically connecting pads;
forming a metal layer on the conductive layer exposed by the openings of the resist layer with an electroplating process, and filling the metal layer in the openings of the insulating protecting layer;
removing the resist layer, and removing part of the metal layer and the conductive layer above the insulating protecting layer with a thinning process, so as to form on each of the electrically connecting pads a metal bump; and
forming an adhesive layer on a surface of the metal bump exposed by each of the openings of the insulating protecting layer, so as to form the electrically connecting structure for electrically connecting the circuit board to an external electronic device.

2. The method for fabricating an electrically connecting structure of a circuit board of claim 1, wherein the adhesive layer is one selected from a group consisting of a solder material, a metal layer and an organic solderability preservative (OSP) layer.

3. The method for fabricating an electrically connecting structure of a circuit board of claim 2, wherein the metal layer is one selected from a group consisting of a nickel/gold bi-metal layer, gold, electroless plating tin and electroless plating silver.

4. The method for fabricating an electrically connecting structure of a circuit board of claim 2 further comprising performing a reflow process on the solder material to form a solder bump on the metal bump.

5. The method for fabricating an electrically connecting structure of a circuit board of claim 1, wherein the metal layer is made of at least one selected from a group consisting of lead, tin, silver and copper.

6. The method for fabricating an electrically connecting structure of a circuit board of claim 1, wherein the thinning process is one selected from a group consisting of an etching, a buff and an abrasive process.

7. A method for fabricating an electrically connecting structure of a circuit board, the method comprising:
providing a circuit board comprising a plurality of electrically connecting pads on at least one surface of the circuit board, and forming on the surface of the circuit board an insulating protecting layer comprising a plurality of openings for exposure of the electrically connecting pads;
forming a conductive layer on the insulating protecting layer and the openings of the insulating protecting layer;
forming a metal layer on the conductive layer with an electroplating process, and filling the metal layer in the openings of the insulating protecting layer;
removing part of the metal layer and the conductive layer above the insulating protecting layer with a thinning process, and keeping a remaining part of the metal layer and the conductive layer filled in the openings of the insulating protecting layer opening, so as to form on each of the electrically connecting pads a metal bump; and
forming an adhesive layer on a surface of the metal bump exposed by each of the openings of the insulating protecting layer, so as to form the electrically connecting structure for electrically connecting the circuit board to an external electronic device.

8. The method for fabricating an electrically connecting structure of a circuit board of claim 7, wherein the adhesive layer is one selected from a group consisting of a solder material, a metal layer and an OSP layer.

9. The method for fabricating an electrically connecting structure of a circuit board of claim 8, wherein the metal layer is one selected from a group consisting of a nickel/gold bi-metal layer, gold, electroless plating tin and electroless plating silver.

10. The method for fabricating an electrically connecting structure of a circuit board of claim 8 further comprising performing a reflow process on the solder material to form a solder bump on the metal bump.

11. The method for fabricating an electrically connecting structure of a circuit board of claim 7, wherein the metal layer is made of at least one selected from a group consisting of lead, tin, silver and copper.

12. The method for fabricating an electrically connecting structure of a circuit board of claim 7, wherein the thinning process is one selected from a group consisting of an etching, a buff and an abrasive process.

13. A method for fabricating an electrically connecting structure of a circuit board, the method comprising:
providing a circuit board comprising a plurality of electrically connecting pads on at least one surface of the circuit board, and forming on the surface of the circuit board an insulating protecting layer having a plurality of openings for exposure of the electrically connecting pads;
forming a conductive layer on the insulating protecting layer and the openings of the insulating protecting layer;
forming on the conductive layer a resist layer having a plurality of openings corresponding to the electrically connecting pads;
forming a metal layer on the conductive layer exposed by the openings of the resist layer with an electroplating process, and filling the metal layer in the openings of the insulating protecting layer;
removing the metal layer and the conductive layer above the insulating protecting layer with a thinning process, and keeping the metal layer and the conductive layer filled in the openings of the insulating protecting layer, so as to form a metal bump on each of the electrically connecting pads; and
removing the resist layer and the conductive layer covered by the resist layer, and forming an adhesive layer on a surface of the metal bump exposed by each of the openings of the insulating protecting layer, so as to form the electrically connecting structure for electrically connecting the circuit board to an external electronic device.

14. The method for fabricating an electrically connecting structure of a circuit board of claim 13, wherein the adhesive layer is one selected from a group consisting of a solder material, a metal layer and an OSP layer.

15. The method for fabricating an electrically connecting structure of a circuit board of claim 14, wherein the metal layer is one selected from a group consisting of a nickel/gold bi-metal layer, gold, electroless plating tin and electroless plating silver.

16. The method for fabricating an electrically connecting structure of a circuit board of claim 14 further comprising performing a reflow process on the solder material to form a solder bump on the metal bump.

17. The method for fabricating an electrically connecting structure of a circuit board of claim 13, wherein the metal layer is made of at least one selected from a group consisting of lead, tin, silver and copper.

18. The method for fabricating an electrically connecting structure of a circuit board of claim 13, wherein the thinning process is performed by the use of an etching process.
